(19) United States
(12) Patent Application Publication
(10) Pub. No.: US 2002/0113605 A1
(43) Pub. Date: Aug. 22, 2002

(54) Rf circuit with capacitive active impedance

(76) Inventors: Lucas Maria Florentinus De Maaijer, Belfeld (NL); Petrus Gerardus Maria Baltus, Eindhoven (NL)

Correspondence Address: U.S. Philips Corporation, 580 White Plains Road, Tarrytown, NY, 10591, US

(21) Appl. No.: 10/056,468

(22) Filed: Jan. 17, 2002

(30) Foreign Application Priority Data
Jan. 18, 2001 (EP) 01200167.3

(51) Int. Cl. G01R 27/26

(52) U.S. Cl. 324/679

(57) ABSTRACT

The present invention relates to a radio frequency circuit, comprising a differential input stage, which links up with a cascaded capacitive stage, wherein the input stage is formed by a pair of transistors and wherein the imaginary part of the input stage current is at least substantially faded out by the capacitive stage. The imaginary part of the input current of a transistor is provided by currents originating from capacitors which are connected between the input node and other nodes in the circuit which have a different phase than the input node. The invention obviates the requirement of very high quality inductors by using internal phase differences on different nodes in an active network and is particularly suited for wireless products such as pagers and mobile telephone.

The present invention relates to a radio frequency circuit comprising a differential input stage.

Such circuits are generally known particularly through application in wireless products like pagers and mobile telephones. An ever existing problem in such circuits is the matching of the impedance thereof with the impedance of connected components, for instance an antenna. In particular the matching of both the real and imaginary part of such impedances may provide for design problems e.g. in the example of the antenna where the impedance is purely real, providing an even more difficult design task at matching the impedances.

A common way for solving such matching problems is to provide for one or more external or integrated inductors. A disadvantage hereof is that very often, certainly in the example provided, the quality factor of such inductors needs to be very high. Typical values range between 20 and 30 and even in access thereof. Such quality factors are quite difficult to realize in production processes for integrated circuits and may render costly produced circuits.

It is an object of the invention to provide an alternative solution obviating the requirement of such high quality inductors in a favourable, cost effective manner, while realising a compensation of at least the imaginary part of an input impedance. According to the invention such may be realized by the features of the characterizing portion of claim 1.

With an arrangement according to the invention, in accordance with the idea underlying the invention, internal phase differences on different nodes in an active circuitry may be used and applied in such a manner that these can compensate the imaginary part of the input impedance.

In particular, with the arrangement according to the invention the imaginary part of the input current of a transistor is provided by currents originating from capacitors which are connected between the input node and other nodes in the circuit which have a different phase than the input. In this manner, a broadband matching is achieved without requiring high quality inductors. The capacitors are used to provide the currents to compensate internal capacitance. This is in a particular elaboration of the invention implemented such that the input impedance is forced to be real.

The invention will further be explained by way of example according to a drawing in which:

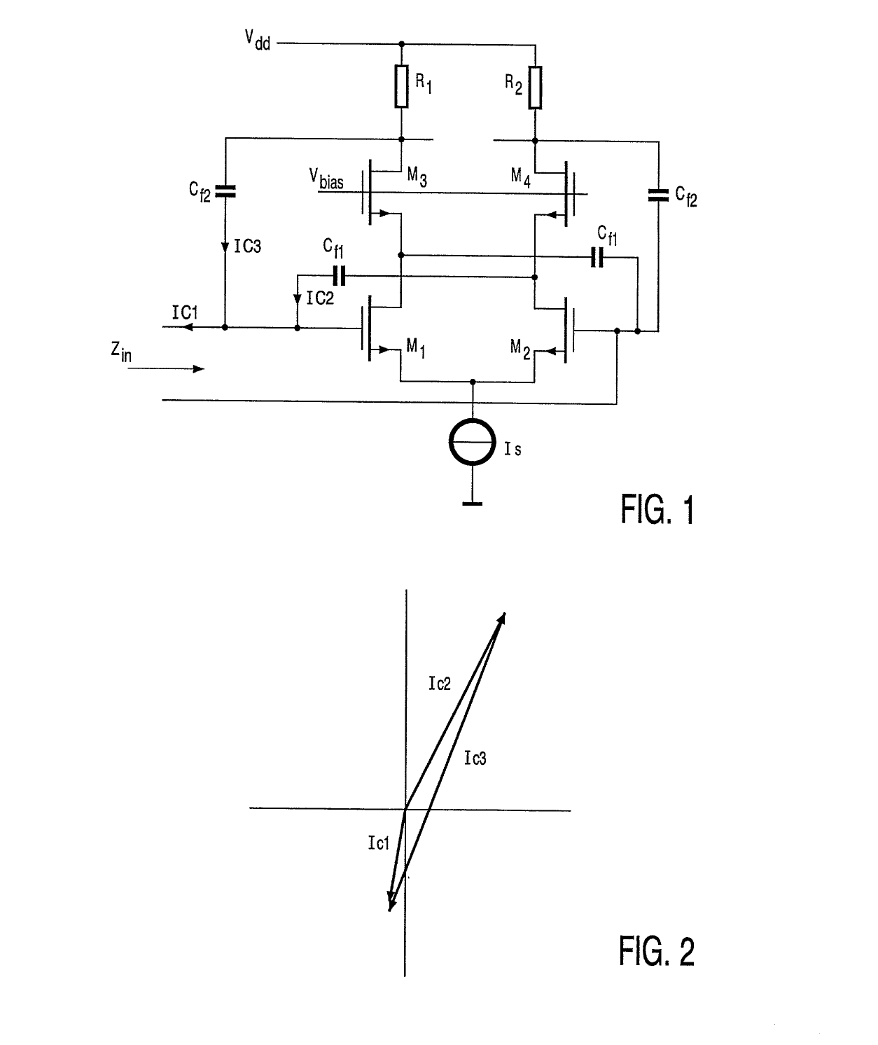

FIG. 1 is a schematic example of a relevant circuit part realising the solution according to the invention;

FIG. 2 is a factor diagram with vectors representing compensatory currents created by a circuit in accordance with the invention, for compensating the features of a main current;

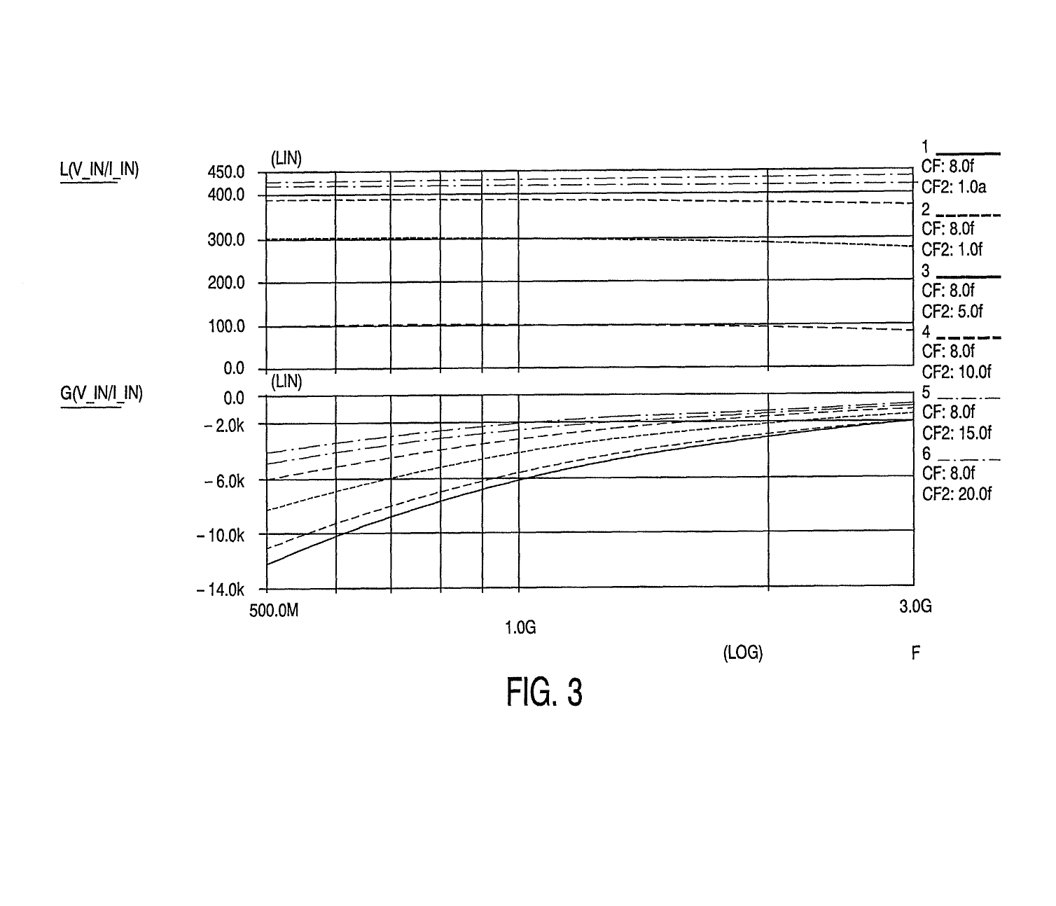

FIG. 3 provides a simulated result of a circuit in accordance with the invention.

FIG. 1 provides an example of a circuit in which the actual input impedance is too high and in which the impedance matching method according to the invention is applied to decrease the imaginary part of the input impedance. In the figure, the circuit according to the invention is fed by a current source Is, which via a split up leads to input transistors M1 and M2, the main path of which further connects to cascade transistors M3 and M4 which are interconnected so as to form bias setting cascade transistors and realising bias tension Vb on the drain sides thereof. The main path of cascade transistors M3 and M4 via resistors R1 and R2 respectively is connected to a supply voltage set on the Vdd lead. The input current, the voltages on the input and the output nodes Vin and Vout, the voltages on the nodes V1 and V2, and the feedback capacitors C_{f1} and C_{f2} are of significant importance in the concept underlying the invention. Due to the different voltages and their phases, the input current of transistor T1 is compensated by a capacitance of suitable value. The choice of such value is made with the aid of a vector diagram like in FIG. 2, which vectors illustrate the created imaginary currents Ic2 and Ic3. In the circuit according to the invention these currents are re-directed so as to form a new, influenced current Ic1. The effect is schematically illustrated in FIG. 2 by the addition of the two vectors Ic2 and Ic3.

FIG. 3 illustrates a result from simulating the network, or circuitry of FIG. 1 in the ordinary manner, in which the upper part of the diagram relates to the real portion of the impedance Vin/Iin, whereas the lower portion relates to the imaginary portion thereof. The Y axis is represented linear, whereas the X axis has a logaritmic scale for the relevant sequencies.

Relational lines are given in the diagram for various values of the combination of C_{f1} and C_{f2} as provided on the righthand side of the graph. The graphs show that at fixed value of C_{f1} the imaginary part of the impedance is reduced at increasing the value of C_{f2} and that at certain values, in this case at C_{f1}=8 f and C_{f2}=15 f, the real part is flat over the entire range for f values.

The present invention thus provides an impedance matching without the use of inductors and without increasing the noise figure of the relevant circuit only at the cost of a slight reduction in gain due to the feedback.

The present invention, apart from the preceding description and the various details of the pertaining figures, further relates to the subjects and features as defined in the following claims.

1. Radio frequency circuit, comprising a differential input stage, characterized in that the input stage links up with a cascaded capacitive stage.

2. Circuit according to claim 1, characterized in that the input stage is formed by a pair of transistors.

3. Circuit according to claim 1 or 2, characterized in that the capacitive stage is formed by a pair of a set of cascaded capacitors (C_{f1}, C_{f2}).

4. Circuit according to claim 1, 2 or 3, characterized in that the imaginary part of an input stage current is at least substantially faded out by the capacitive stage.

5. Circuit according to any of the preceding claims, characterized in that the capacitive stage comprises two capacitors (C_{f1}, C_{f2}) of different capacitive value.

6. Circuit according to claim 5, characterized in that one of the capacitors (C_{f1}) is cross-linked to the main path of the other of a pair of transistors.

7. Circuit according to any of the preceding claims characterized in that the imaginary part of the input current of a transistor is provided by currents originating from capacitors which are connected between the input node and other nodes in the circuit which have a different phase than the input node.

8. Electronic device, in particular wireless product provided with a radio frequency circuit according to any of the preceding claims.
